(19) United States
(12) Patent Application Publication
(10) Pub. No.: US 2025/0309015 A1
(43) Pub. Date: Oct. 2, 2025

(54) INTEGRATED CIRCUIT PACKAGES INCLUDING A GLASS-CORE SUBSTRATE WITH ULTRA-HIGH ASPECT RATIO THROUGH-GLASS VIAS

(71) Applicant: Intel Corporation, Santa Clara, CA (US)

(72) Inventors: Jeremy Ecton, Gilbert, AZ (US); Brandon C. Marin, Gilbert, AZ (US); Srinivas Venkata Ramanuja Pietambaram, Chandler, AZ (US); Bohan Shan, Chandler, AZ (US); Gang Duan, Chandler, AZ (US)

(73) Assignee: Intel Corporation, Santa Clara, CA (US)

(21) Appl. No.: 18/618,069

(22) Filed: Mar. 27, 2024

(51) Int. Cl. H01L 23/15; H01L 23/00; H01L 23/498; H01L 25/065

(52) U.S. Cl. CPC H01L 23/15; H01L 23/49816; H01L 23/49838; H01L 24/08; H01L 24/16; H01L 25/0655; H01L 2224/08146; H01L 2224/08225; H01L 2224/16146; H01L 2224/16227; H01L 2924/01029; H01L 2924/1052; H01L 2924/1431; H01L 2924/1434; H01L 2924/15311

(57) ABSTRACT

Disclosed herein are microelectronic assemblies and related devices and methods. In some embodiments, a microelectronic assembly may include a first glass layer including a first conductive through-glass via (TGV); and a second glass layer including a second conductive TGV, wherein the second glass layer is on and bonded to the first glass layer, the second conductive TGV is electrically coupled to the first conductive TGV, and the first conductive TGV and the second conductive TGV have an aspect ratio between 20:1 and 50:1.

### BACKGROUND

Electronic circuits when fabricated on a wafer of semiconductor material, such as silicon, are commonly called integrated circuits (ICs). The wafer with such ICs is typically cut into numerous individual dies. IC devices (e.g., dies) are typically coupled together in a multi-die IC package to integrate features or functionality and to facilitate connections to other components, such as package substrates. An IC package may include an embedded multi-die interconnect bridge (EMIB) for coupling two or more dies. An IC package may be integrated onto an electronic system, such as a consumer electronic system. Some ICs have specific functionalities, such as memory or processing. Some other ICs have multiple functionalities, such as a system-on-chip (SOC), in which all or most components of a computer or other electronic system are integrated into a single monolithic die.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A and 1B are schematic cross-sectional views of example microelectronic assemblies according to some embodiments of the present disclosure.

FIGS. 2A-2C are schematic cross-sectional views of example microelectronic assemblies according to some embodiments of the present disclosure.

FIGS. 3A-3C are schematic cross-sectional views of magnified portions of example microelectronic assemblies according to some embodiments of the present disclosure.

FIGS. 4A-4C are schematic cross-sectional views of example microelectronic assemblies according to some embodiments of the present disclosure.

FIGS. 5A-5G are simplified cross-sectional views illustrating various manufacturing steps of an example microelectronic assembly according to some embodiments of the present disclosure.

FIG. 6 is a cross-sectional view of a device package that may include one or more microelectronic assemblies in accordance with any of the embodiments disclosed herein.

FIG. 7 is a cross-sectional side view of a device assembly that may include one or more microelectronic assemblies in accordance with any of the embodiments disclosed herein.

FIG. 8 is a block diagram of an example computing device that may include one or more microelectronic assemblies in accordance with any of the embodiments disclosed herein.

### DETAILED DESCRIPTION

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in a way that limits the broad scope of the present disclosure and its potential applications.

Die partitioning, in which multiple smaller dies are coupled together by high-density interconnects, may achieve smaller form factors and higher yields than utilizing a single, monolithic die. However, coupling dies together at the fine pitch needed to achieve desired interconnect density has been limited by conventional approaches. One approach to achieving a finer pitch includes incorporating a thin glass core into a package substrate.

The structures and assemblies disclosed herein may include a glass core, also referred to herein as a “glass layer,” with through-glass vias (TGVs) extending through the glass core for front-to-back connections between two different substrates. A substrate may include a dielectric material with conductive pathways therein that are typically formed on a surface of the glass core. The conductive pathways through the dielectric material may provide routing for design flexibility, and the uniform diameters of the TGVs may provide dimensional stability and improved connectivity. A glass core as compared to a conventional epoxy core offers several advantages including higher through-glass via (TGV) density, lower signal losses, and lower total thickness variation (TTV), among others. Another advantage is a glass core enables higher aspect ratio TGVs. Higher aspect ratio TGVs are required to achieve the finer pitches that are desired. One limitation with glass core is the maximum TGV aspect ratio. Typically, a glass core in substrate having a thickness between 200 microns and 1500 microns is limited to TGVs having a maximum aspect ratio of 10:1. Various ones of the embodiments disclosed herein may achieve ultra-high aspect ratio TGVs, for example, aspect ratio TGVs of greater than 10:1, and may further help reduce the cost and complexity assembling multi-die IC packages relative to conventional approaches and increase reliability and functionality of these IC packages during use.

Accordingly, disclosed herein are microelectronic assemblies including a microelectronic assembly may include a first glass layer including a first conductive through-glass via (TGV); and a second glass layer including a second conductive TGV, wherein the second glass layer is on and bonded to the first glass layer, the second conductive TGV is electrically coupled to the first conductive TGV, and the first conductive TGV and the second conductive TGV have an aspect ratio between 20:1 and 50:1.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are stated in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may include substantially monocrystalline semiconductors, such as silicon or germanium, as a base material on which integrated circuits are fabricated with traditional semiconductor processing methods. The semiconductor base material may include, for example, N-type or P-type materials. Dies may include, for example, a crystalline base material formed using a bulk silicon (or other bulk semiconductor material) or a semiconductor-on-insulator (SOI, e.g., a silicon-on-insulator) structure. In some other embodiments, the base material of one or more of the IC dies may include alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group Ill-N, group Ill-V, group II-VI, or group IV materials. In yet other embodiments, the base material may include compound semiconductors, for example, with a first sub-lattice of at least one element from group Ill of the periodic table (e.g., Al, Ga, In), and a second sub-lattice of at least one element of group V of the periodic table (e.g., P, As, Sb). In yet other embodiments, the base material may include an intrinsic IV or Ill-V semiconductor material or alloy, not intentionally doped with any electrically active impurity; in alternate embodiments, nominal impurity dopant levels may be present. In still other embodiments, dies may include a non-crystalline material, such as polymers; for example, the base material may include silica-filled epoxy. In other embodiments, the base material may include high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of input/output (I/O) functions, arithmetic operations, pipelining of data, etc.).

In another example, the terms “package” and “IC package” are synonymous, as are the terms “die” and “IC die.” Note that the terms “chip,” “chiplet,” “die,” and “IC die” are used interchangeably herein.

The term “optical structure” includes arrangements of forms fabricated in ICs to receive, transform and/or transmit optical signals as described herein. It may include optical conductors such as waveguides, electromagnetic radiation sources such as lasers and light-emitting diodes (LEDs) and electro-optical devices such as photodetectors.

In various embodiments, any photonic IC (PIC) described herein may include a semiconductor material, for example, N-type or P-type materials. The PIC may include, for example, a crystalline base material formed using a bulk silicon (or other bulk semiconductor material) or a SOI structure (or, in general, a semiconductor-on-insulator structure). In some embodiments, the PIC may be formed using alternative materials, which may or may not be combined with silicon, that include, but are not limited to, lithium niobite, indium phosphide, silicon dioxide, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group Ill-N or group IV materials. In some embodiments, the PIC may include a non-crystalline material, such as polymers. In some embodiments, the PIC may be formed on a printed circuit board (PCB). In some embodiments, the PIC may be inhomogeneous, including a carrier material (such as glass or silicon carbide) as a base material with a thin semiconductor layer over which is an active side comprising transistors and like components. Although a few examples of the material for the PIC are described here, any material or structure that may serve as a foundation upon which the PIC may be built falls within the spirit and scope of the present disclosure.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., metal oxide semiconductor (MOS) FETs (MOSFETs). In general, a FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are included in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a PIC, “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO2), borosilicate (e.g., 70-80 wt % SiO2, 7-13 wt % of B203, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material includes interlayer low-k dielectric that is provided within the IC die. Within package substrates, and printed circuit boards (PCBs) such insulating material includes organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substrate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI). Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects. In some embodiments, the pitch of the DTD interconnects may be different from the pitch of the DTPS interconnects, although, in other embodiments, these pitches may be substantially the same.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may include the same or different insulating materials. In some embodiments, the levels of underfill may include thermoset epoxies with silicon oxide particles; in some embodiments, the levels of underfill may include any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable dielectrics, dry film photoimageable dielectrics, acrylics, solvents) may be provided in an IC package described herein and may not be labeled or shown to avoid cluttering the drawings. Solder resist may be a liquid or dry film material including photoimageable dieletrics. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

Coordinates, when included in the accompanying drawings, identify a thickness or a height by z-dimension, a width by x-dimension, and a length by y-dimension. A diameter or cross section may be identified by xy-dimension.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

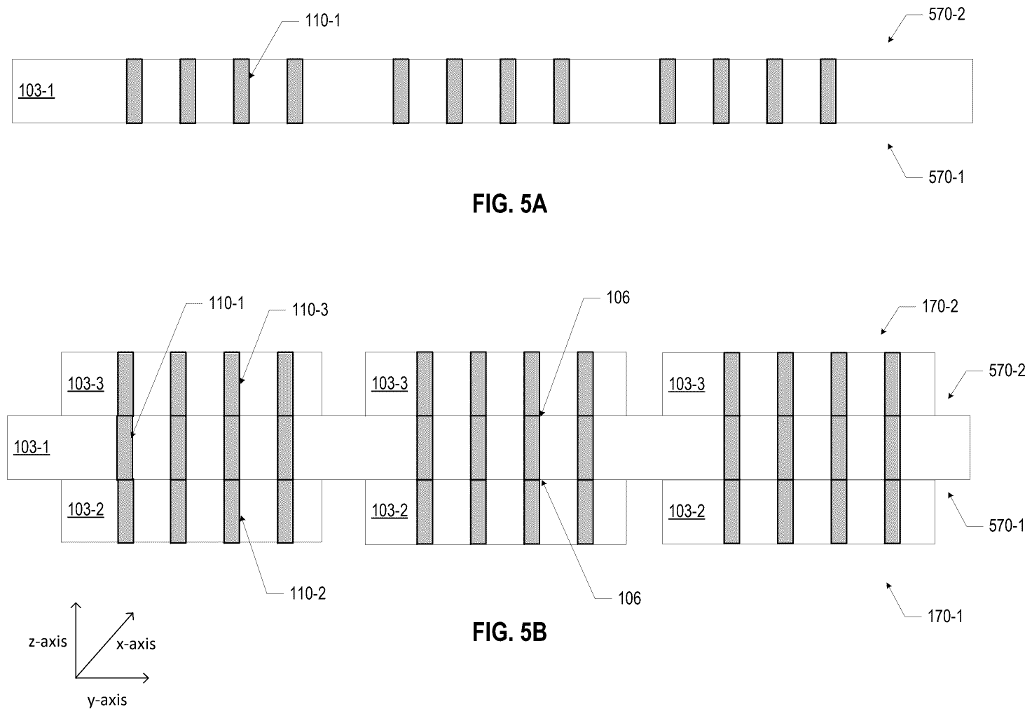

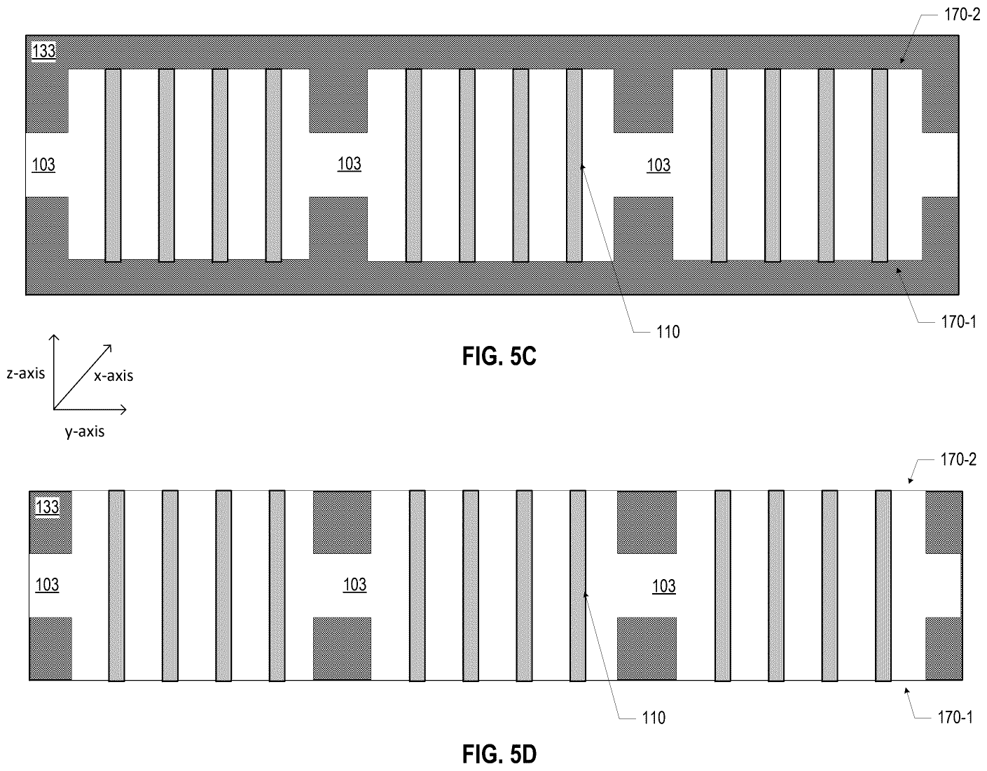

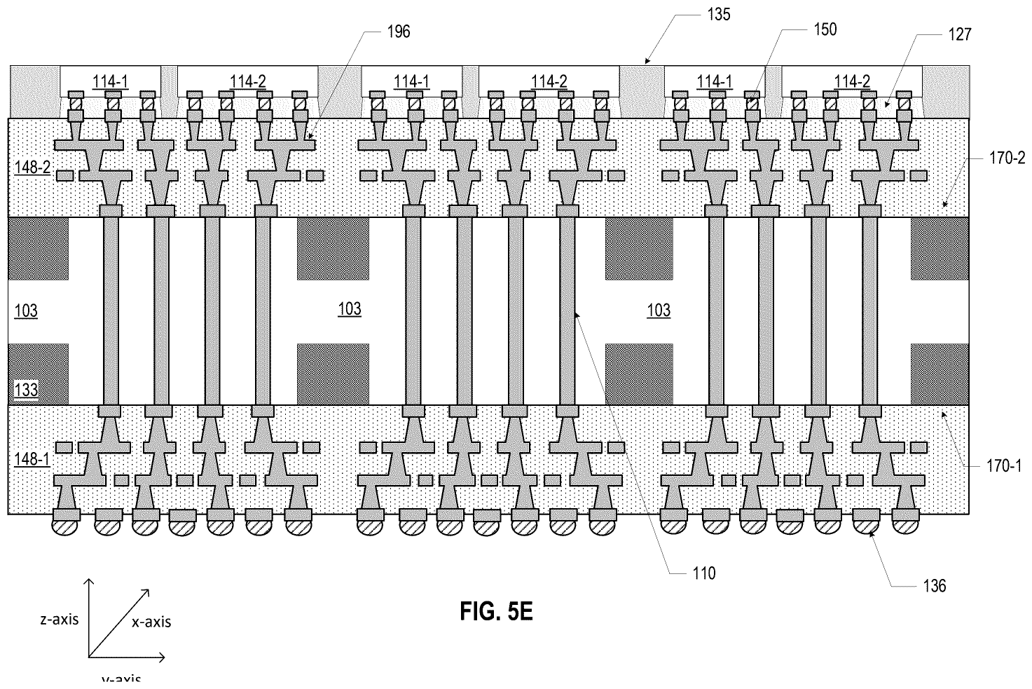

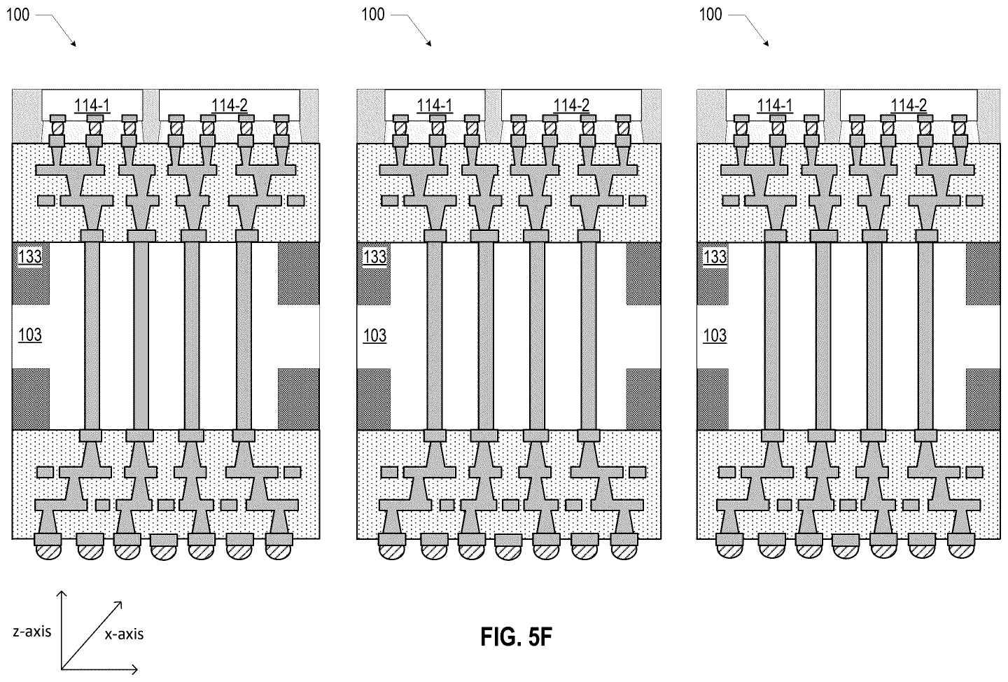

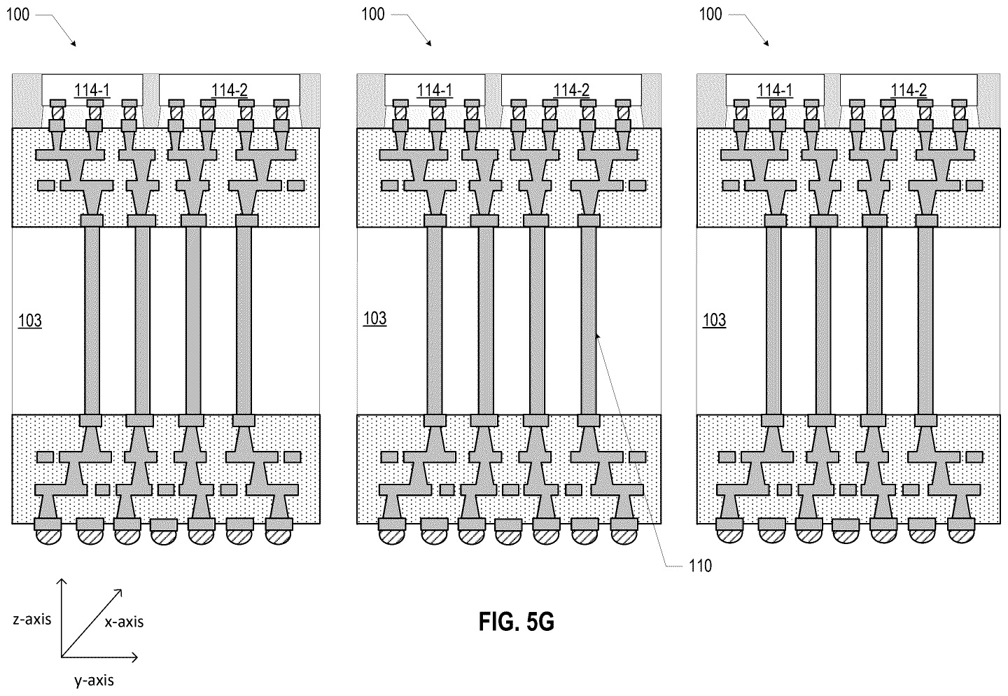

For convenience, if a collection of drawings designated with different letters are present (e.g., FIGS. 5A-5G), such a collection may be referred to herein without the letters (e.g., as “FIG. 5”). Similarly, if a collection of reference numerals designated with different numbers and/or letters are present (e.g., 148-1, 148-2), such a collection may be referred to herein without the numbers (e.g., as “148”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

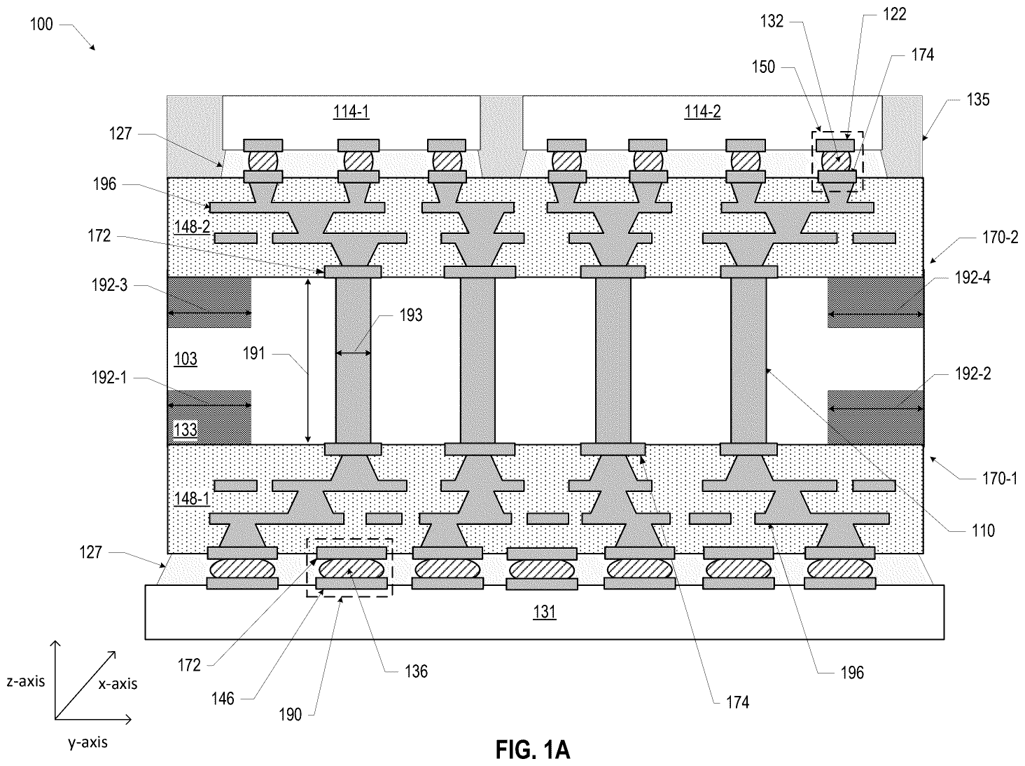

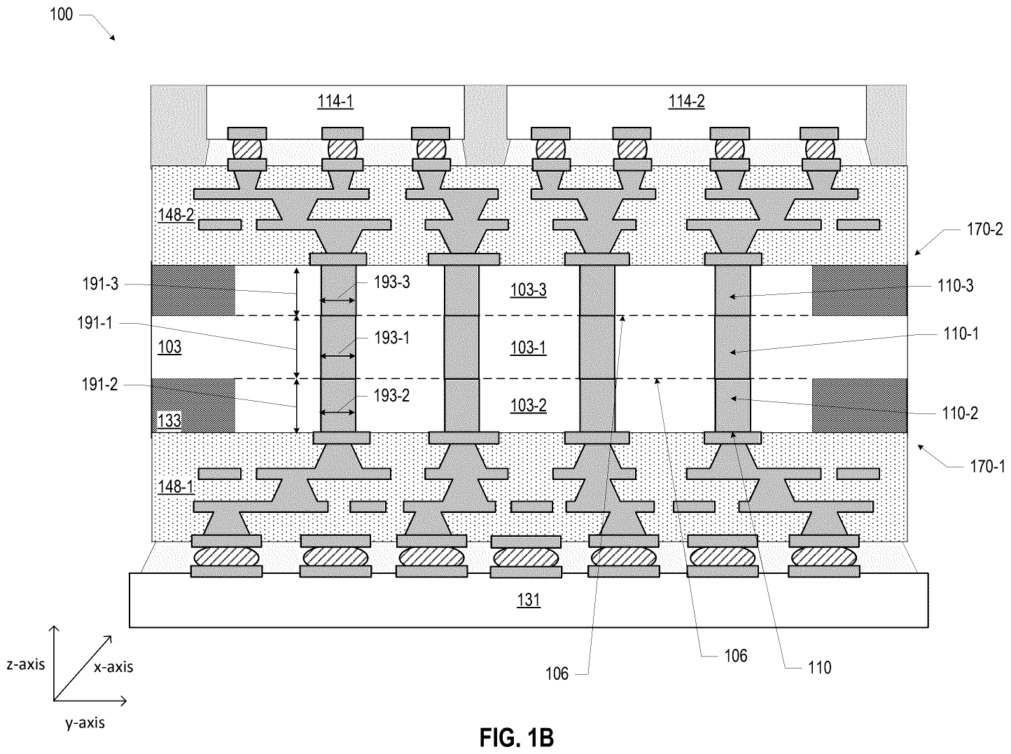

FIG. 1A is a schematic cross-sectional view of an example microelectronic assembly 100 according to some embodiments of the present disclosure. Microelectronic assembly 100 may include a core 103 having a first surface 170-1 and an opposing second surface 170-2 with ultra-high aspect ratio TGVs 110. An aspect ratio of a TGV 110 is the ratio of an overall thickness 191 (e.g., z-dimension or z-height) of the TGV to a diameter 193 (e.g., xy-dimension) of the TGV (e.g., a TGV having a thickness of 200 microns and a diameter of 20 microns has an aspect ratio equal to 10:1). As used herein, an “ultra-high aspect ratio TGV” refers to a TGV having an aspect ratio that is greater than 10:1. For example, an ultra-high aspect ratio TGV 110 may have an aspect ratio between 20:1 and 50:1, (e.g., between 20:1 and 30:1, or between 30:1 and 50:1).

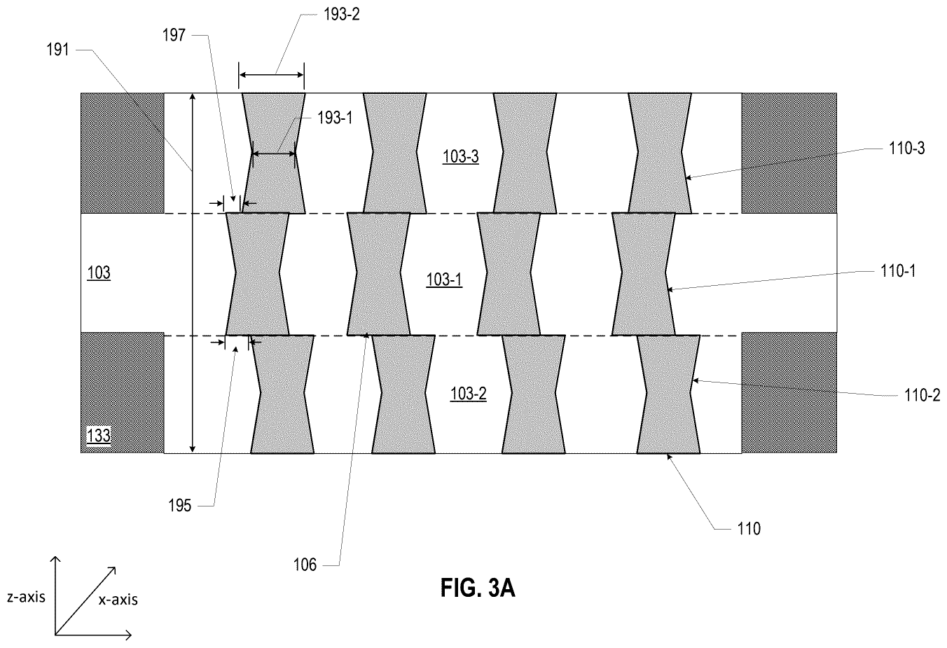

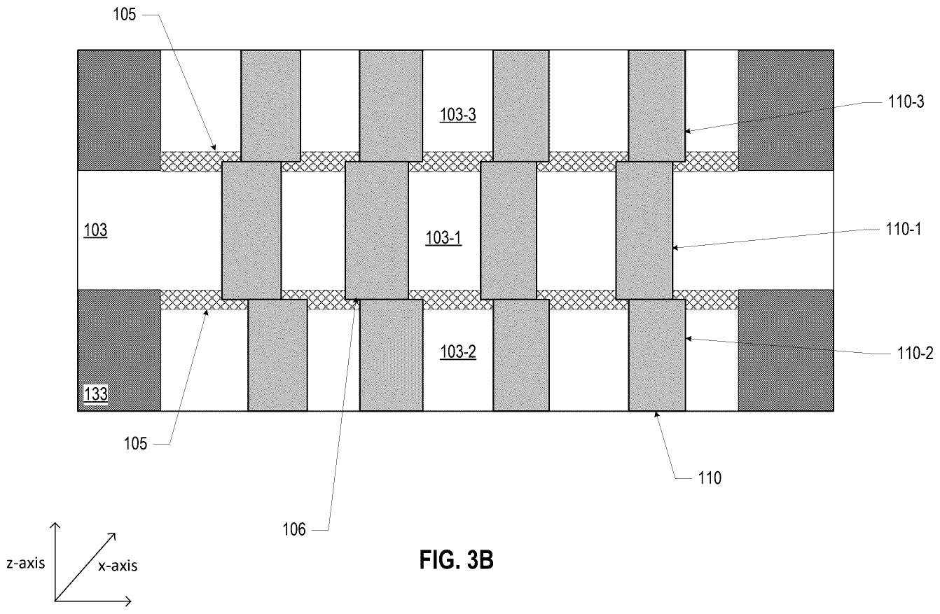

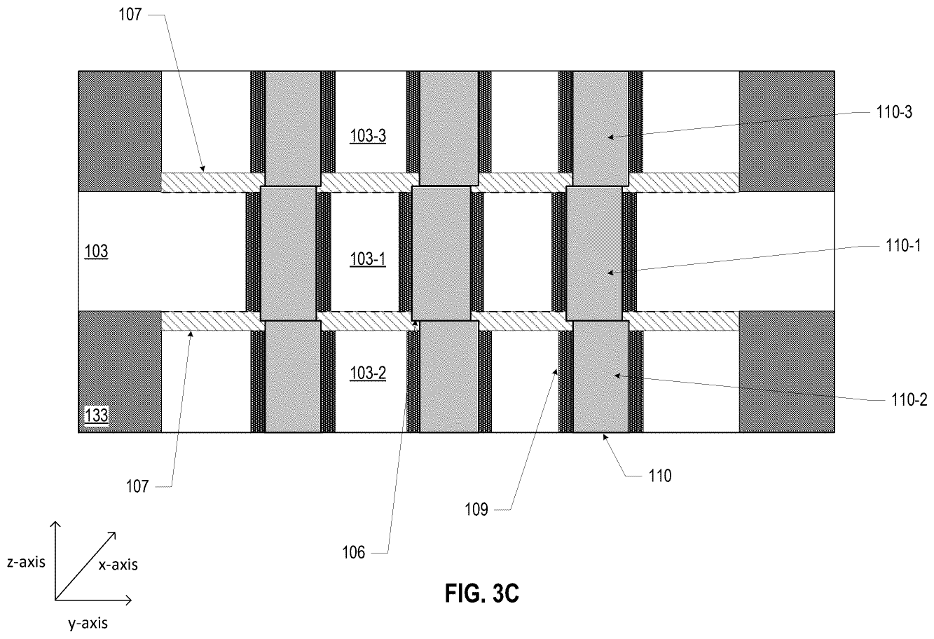

TGVs 110 may have any suitable size and shape. A thickness 191 of the individual TGVs 110 may be between 100 microns and 2 millimeters (i.e., between 200 microns and 1 millimeter). A diameter 193 of the individual TGVs 110 may be between 5 microns and 100 microns (e.g., between 20 microns and 50 microns). TGVs 110 are shown in FIG. 1A as having straight, parallel sides; however, in various embodiments, the sides may be tapered, tapered towards a center (e.g., have an hourglass shape, as shown in FIG. 3A), and/or have other irregularities depending on the processing conditions for generating TGVs 110. TGVs 110 may be formed using any suitable process, including, for example, laser drilling via openings through the core 103 and depositing a conductive material in the openings. TGVs 110 may be formed of any suitable conductive material, such as copper, silver, nickel, gold, aluminum, or other metals or alloys. In some embodiments, a pitch of the TGVs 110 may be between 25 microns and 200 microns (e.g., between 75 microns and 150 microns).

A material of the core 103 may include glass, such as bulk transparent glass, and also may be referred to herein as “a glass layer.” As used herein, the term “core” refers to a structure (e.g., a portion of a glass layer) of any glass material such as quartz, silica, fused silica, silicate glass (e.g., borosilicate, aluminosilicate, alumino-borosilicate), soda-lime glass, soda-lime silica, borofloat glass, lead borate glass, photosensitive glass, non-photosensitive glass, or ceramic glass. In particular, the core 103 may be bulk glass or a solid volume/layer of glass, as opposed to, e.g., materials that may include particles of glass, such as glass fiber reinforced polymers. Such glass materials are typically non-crystalline, often transparent, amorphous solids. In some embodiments, the core 103 may be an amorphous solid glass layer. In some embodiments, the core 103 may include silicon and oxygen, as well as any one or more of aluminum, boron, magnesium, calcium, barium, tin, sodium, potassium, strontium, phosphorus, zirconium, lithium, titanium, and zinc. In some embodiments, the core 103 may include a material, e.g., any of the materials described above, with a weight percentage of silicon being at least about 0.5%, e.g., between about 0.5% and 50%, between about 1% and 48%, or at least about 23%. For example, if the core 103 is fused silica, the weight percentage of silicon may be about 47%. In some embodiments, the core 103 may include at least 23% silicon and/or at least 26% oxygen by weight, and, in some further embodiments, the core 103 may further include at least 5% aluminum by weight. In some embodiments, the core 103 may include any of the materials described above and may further include one or more additives such as Al₂O₃, B₂O₃, MgO, CaO, SrO, BaO, SnO₂, Na₂O, K₂O, SrO, P₂O₃, ZrO₂, Li₂O, Ti, and Zn. In some embodiments, the core 103 may be a layer of glass that does not include an organic adhesive or an organic material. The core 103 may be distinguished from, for example, the “prepreg” or “RF4” core of a PCB substrate which typically includes glass fibers embedded in a resinous organic material such as an epoxy. In some embodiments, a cross-section of the core 103 in an x-z plane, a y-z plane, and/or an x-y plane of an example coordinate system, shown in FIG. 1A, may be substantially rectangular. In some embodiments, a thickness of a core 103 may be between 50 microns and 2 millimeters (i.e., between 100 microns and 1 millimeter) (e.g., a thickness of core 103 may be equal to a thickness 191 of TGVs 110). In some embodiments, as shown in FIG. 1A, a core 103 has a tiered or stepped contour, where a portion of the core is larger by a length 192 (e.g., y-dimension). A length 192 may be between 10 microns and 25 millimeters (e.g., between 10 microns and 10 millimeters, or between 5 millimeters and 25 millimeters). A length 192 may depend on an xy-dimension of a core 103 (e.g., a larger xy-dimension of 250 millimeters by 250 millimeters may have a larger length 192 of up to 25 millimeters and a smaller xy-dimension of 50 millimeters by 50 millimeters may have a smaller length 192 of up to 10 millimeters) or a method of singulation, as described below with reference to FIGS. 5F and 5G. In some embodiments, individual lengths 192-1, 192-2, 192-3, 192-4, may be a same length (e.g., substantially equal). In some embodiments, individual lengths 192-1, 192-2, 192-3, 192-4, may be different lengths (e.g., varying).

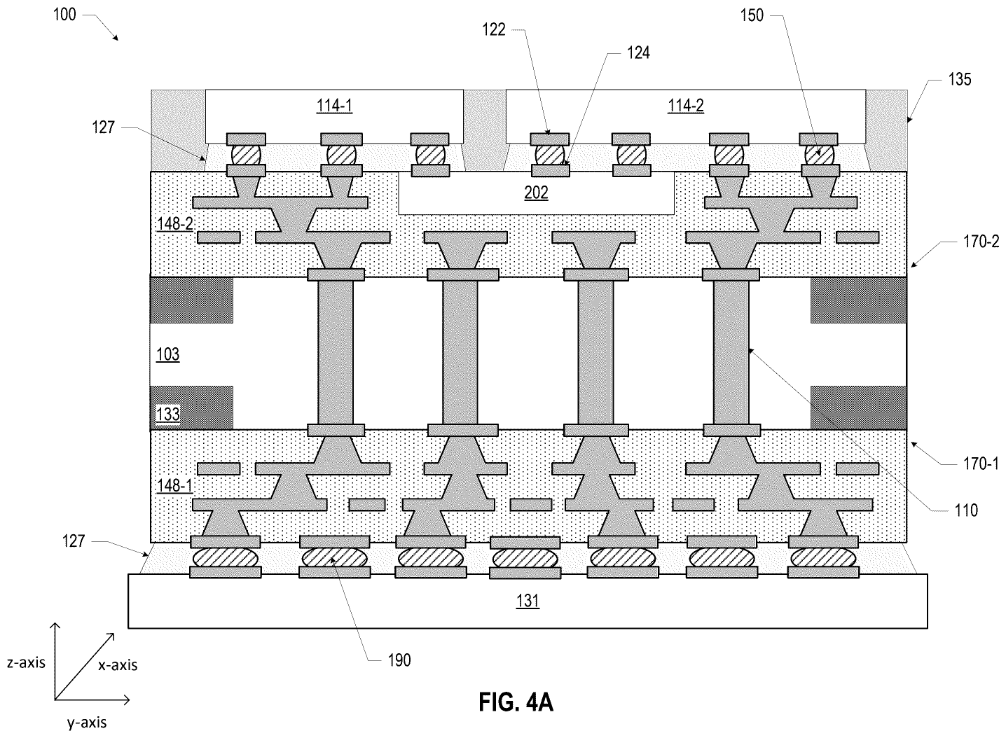

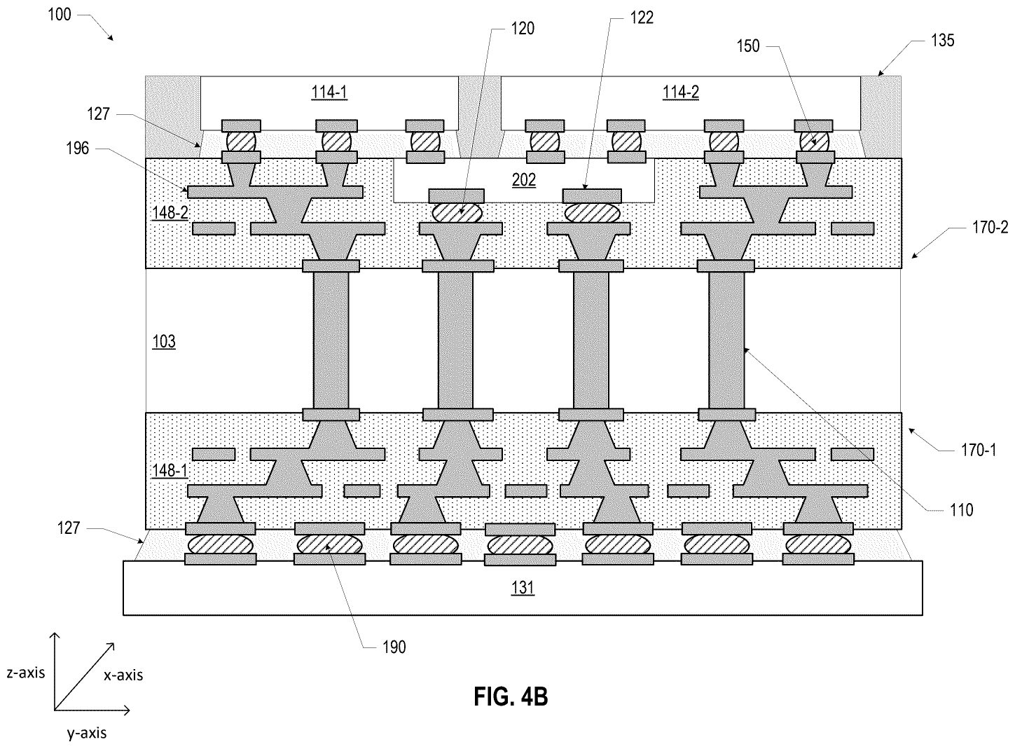

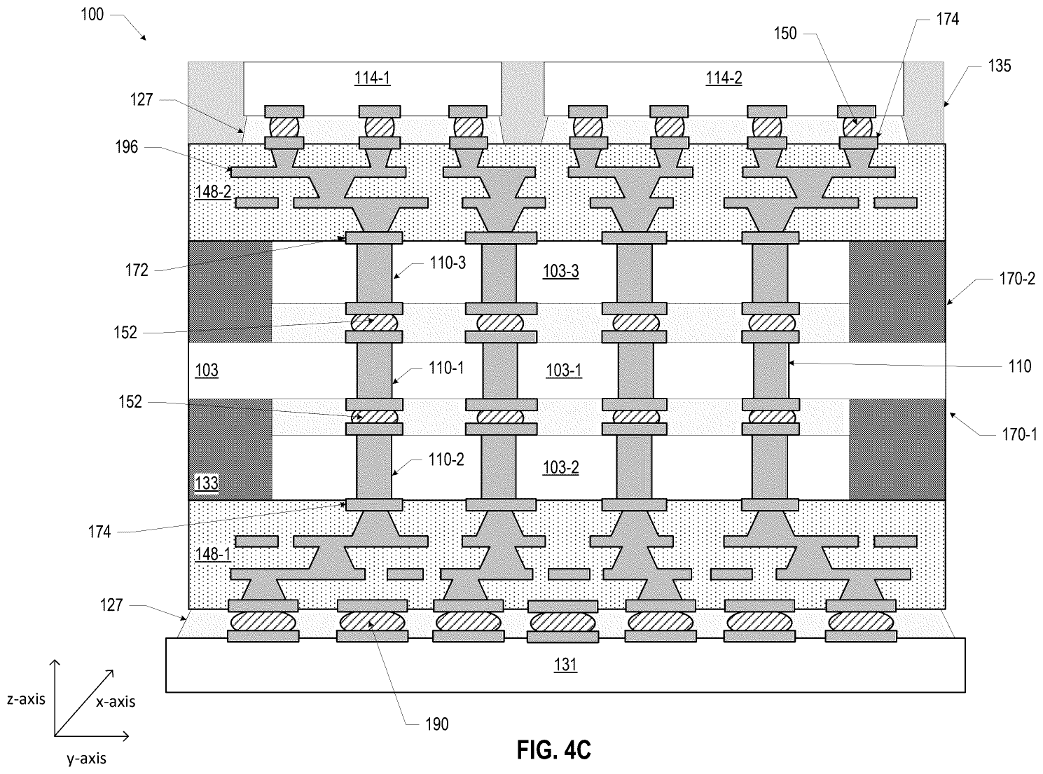

The microelectronic assembly 100 of FIG. 1A may also include an insulating material 133 that encapsulates the core 103. The insulating material 133 may extend from a top surface of the first substrate 148-1 to a bottom surface of the second substrate 148-2 around the core 103 to fill the area formed by the different lengths 192. In some embodiments, the insulating material 133 may be a mold material, such as an organic polymer with inorganic silicon oxide or aluminum oxide particles, a resin material, an epoxy material, or a dielectric material. In some embodiments, the insulating material 133 may be omitted (e.g., as shown in FIG. 4B).

As shown in FIG. 1B, the core 103 having ultra-high aspect ratio TGVs 110 may be formed in layers. In particular, a first glass layer 103-1 may include first TGVs 110-1 having a first thickness 191-1 and a first diameter 193-1, a second glass layer 103-2 may include second TGVs 110-2 having a second thickness 191-2 and a second diameter 193-2, and a third glass layer 103-3 may include third TGVs 110-3 having a third thickness 191-3 and a third diameter 193-3. The first, second, and third glass layer 103-1, 103-2, 103-3 may be stacked, with the first, second, and third TGVs 110-1, 110-2, 110-3 aligned vertically, and bonded together to form the core 103 and TGVs 110. The first, second, and third thicknesses 191-1, 191-2, 191-3 may be between 50 microns and 1 millimeter (e.g., between 50 microns and 500 microns). In some embodiments, the first, second, and third thicknesses 191-1, 191-2, 191-3 may have a same thickness (e.g., a thickness that is substantially the same (i.e., within +/−20%)). In some embodiments, one or more of the first, second, and third thicknesses 191-1, 191-2, 191-3 may have a different thickness. The first, second, and third diameters 193-1, 193-2, 193-3 may be between 5 microns and 100 microns (e.g., between 10 microns and 70 microns). In some embodiments, the first, second, and third diameters 193-1, 193-2, 193-3 may have a same diameter (e.g., a diameter that is substantially the same (i.e., within +/−20%)). In some embodiments, one or more of the first, second, and third diameters 193-1, 193-2, 193-3 may have a different diameter; for example, the first diameter 193-1 may be greater than the second diameter 193-2 and/or the third diameter 193-3 for improved alignment and reduced offset (e.g., offset 195, 197 as shown in FIG. 3A).

The individual glass layers 103-1, 103-2, 103-3 may be bonded together by interconnects 106. Interconnects 106 may extend along an interface area (e.g., xy-dimension) between the individual glass layers 103-1, 103-2, 103-3. An interconnect 106 may include, for example, a hybrid bond having a metal-metal bond (e.g., TGV 110-1-TGV 110-2 bond and TGV 110-1-TGV 110-3 bond) formed between the conductive material of the TGVs 110-1, 110-2, 110-3, and oxide-oxide bond formed between the glass of the glass layers 103-1, 103-2, 103-3 (e.g., first glass layer 103-1 to second glass layer 103-2 bonds and first glass layer 103-1 to third glass layer 103-3 bonds). The glass material in the glass layers surrounding the bond pads may bond with each other. The dielectric material may include an inorganic dielectric (e.g., silicon and oxygen in the form of silicon oxide) or an organic dielectric (e.g., polyimide). The bonded metal and dielectric materials form interconnect 106, comprising hybrid bonds, providing electrical and mechanical coupling. After hybrid bonding the glass layers 103-1, 103-2, 103-3 and TGVs 110-1, 110-2, 110-3, in some embodiments, the individual glass layers 103-1, 103-2, 103-3 and/or individual TGVs 110-1, 110-2, 110-3 may be undetectable (e.g., a seamless core 103 and aligned TGV 110, as shown in FIG. 1A). In some embodiments, individual TGVS 110-1, 110-2, 110-3 may be detected due to a vertical misalignment (e.g., offset 195, 197, as shown in FIG. 3A). In some embodiments, the individual glass layers 103-1, 103-2, 103-3 may be detected due to an interface seam or a dielectric material between layers for bonding (e.g., forming oxide-oxide bonds), as shown in FIGS. 3B and 3C.

Turning back to FIG. 1A, the microelectronic assembly 100 may further include a first substrate 148-1 at the first surface 170-1 of the core 103 and a second substrate 148-2 at the second surface 170-2 of the core 103. The first and second substrates 148-1, 148-2 may include conductive pathways 196 (e.g., including conductive traces and/or conductive vias, as shown) through a dielectric material. The substrates 148 may include a set of first conductive contacts 172 at the bottom surface of the substrate 148 and a set of second conductive contacts 174 at the top surface of the substrate 148, where the conductive pathways 196 electrically couple individual ones of the first and second conductive contacts 172, 174. The first and second substrates 148-1, 148-2 may be manufactured using any suitable technique, such as a semi-additive process, a subtractive etching technique, or other conventional substrate package techniques. In some embodiments, a dielectric material of the substrate 148 may include bismaleimide triazine (BT) resin, polyimide materials, epoxy materials (e.g., glass reinforced epoxy matrix materials, epoxy build-up films, or the like), mold materials, oxide-based materials (e.g., silicon dioxide or spin on oxide), or low-k and ultra low-k dielectric (e.g., carbon-doped dielectrics, fluorine-doped dielectrics, porous dielectrics, and organic polymeric dielectrics). The TGVs 110 in the core 103 may electrically couple the first and second substrates 148-1, 148-2. As used herein, the core 103 with the second substrate 148-2 and/or the first substrate 148-1 may be referred to as a package substrate. TGVs 110 in core 103 may enable power, ground and signal connectivity to components located on either side of the core 103, for example, between dies 114-1, 114-2 and a circuit board 131.

The microelectronic assembly 100 may further include die 114-1 and die 114-2 electrically coupled to a top surface of the second substrate 148-2 by interconnects 150. In particular, conductive contacts 122 on a bottom surface of die 114-1, 114-2 may be electrically and mechanically coupled to conductive contacts 174 at a top surface of the second substrate 148-2 by interconnects 150.

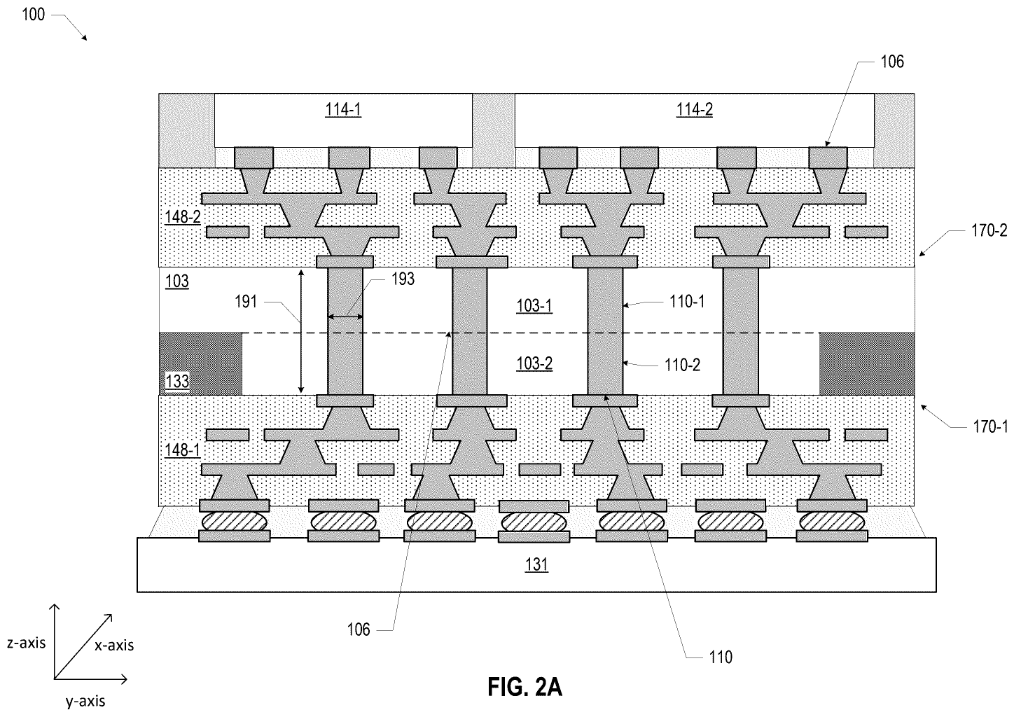

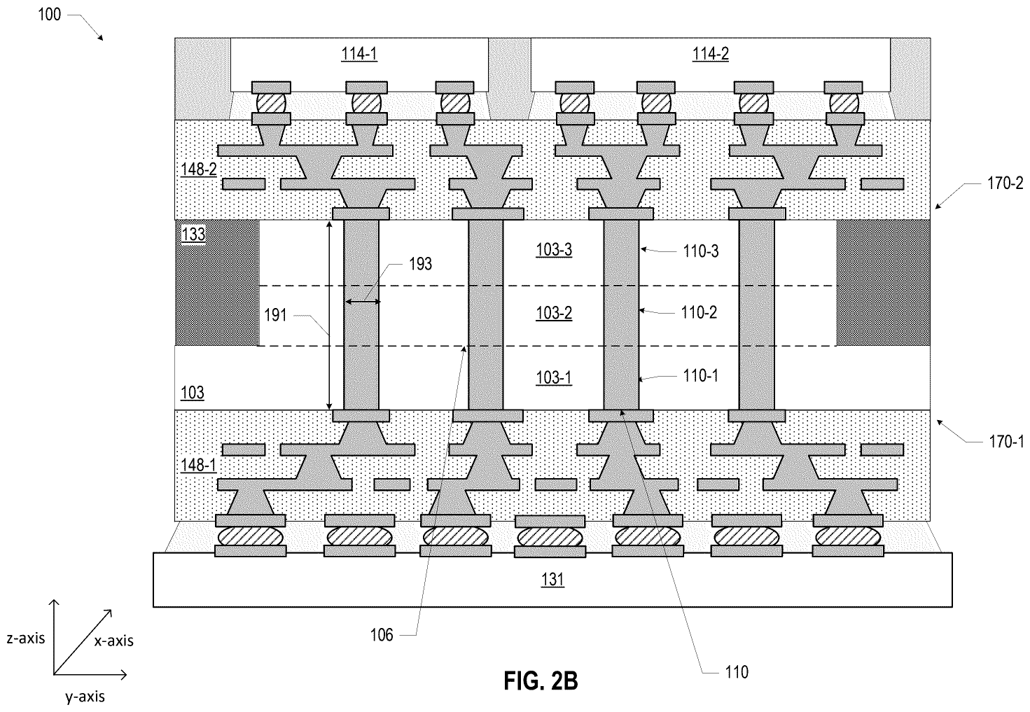

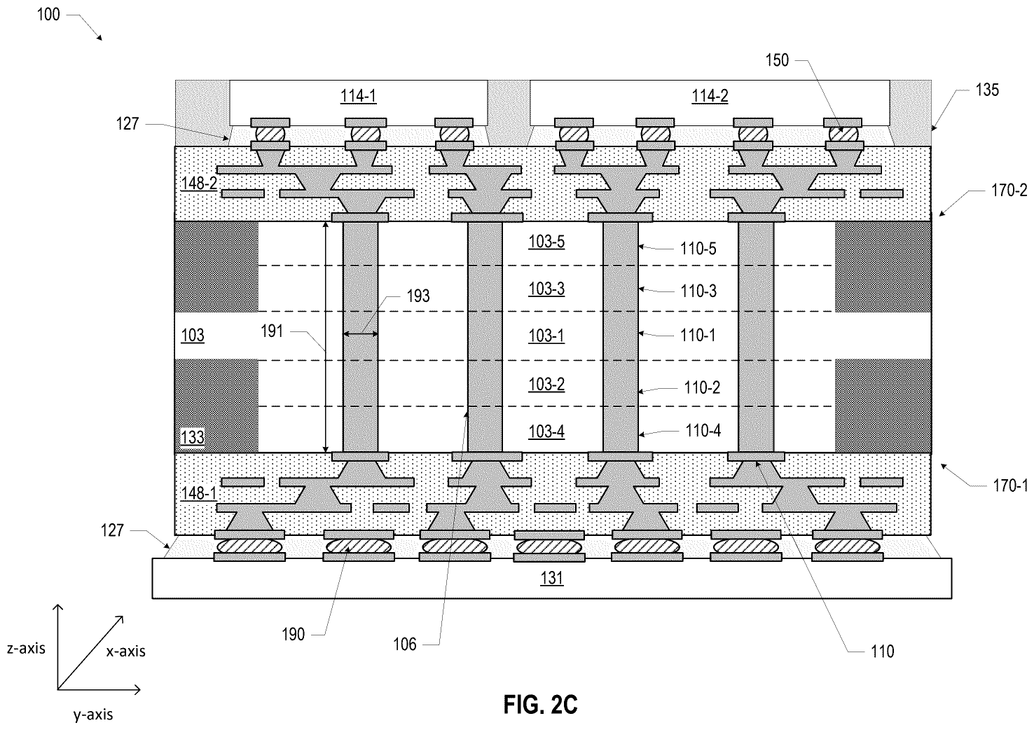

Interconnects 150 may enable electrical coupling between die 114-1 and die 114-2 through conductive pathways 196 in substrate 148-2. Interconnects 150 disclosed herein may take any suitable form. In some embodiments, a set of interconnects 150 may include solder 132 (e.g., solder bumps or balls that are subject to a thermal reflow to form the interconnects 150). Interconnects 150 that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of interconnects 150 may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression. In some embodiments, interconnects 150 disclosed herein may have a pitch between about 18 microns and 75 microns. Although FIG. 1A shows dies 114-1, 114-2 electrically coupled to substrate 148-2 by interconnects 150, dies 114-1, 114-2 may be electrically coupled by any suitable interconnects, including interconnects 106 (e.g., hybrid bonding, as shown in FIG. 2A) and may have a pitch between 2 microns and 70 microns.

The die 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a Ill-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). The conductive pathways in the dies 114 may be bordered by liner materials, such as adhesion liners and/or barrier liners, as suitable. In some embodiments, the die 114 is a wafer. In some embodiments, the die 114 is a monolithic silicon, a fan-out or fan-in package die, or a die stack (e.g., wafer stacked, die stacked, or multi-layer die stacked). In various embodiments, die 114 may include, or be a part of, one or more of a central processing unit (CPU), a memory device (e.g., a high-bandwidth memory device), a logic circuit, input/output circuitry, a transceiver such as a field programmable gate array transceiver, a gate array logic such as a field programmable gate array logic, of a power delivery circuitry, a Ill-V or a Ill-N device such as a Ill-N or Ill-N amplifier (e.g., GaN amplifier), Peripheral Component Interconnect Express (PCIe) circuitry, Double Data Rate (DDR) transfer circuitry, or other electronic components known in the art. In some embodiments, die 114-1 and die 114-2 may include different functionalities. As used herein, the term “functionality” with reference to a die refers to one or more functions (e.g., capability, task, operation, action, instruction execution, etc.) that the die in question can perform. For example, die 114-1 may be a CPU and die 114-2 may be a Graphics Processing Unit (GPU) or memory. In other embodiments, die 114-1 and die 114-2 may include the same or similar functionalities. For example, die 114-1 and die 114-2 may each include memory.

The microelectronic assembly 100 of FIG. 1A may also include an overmold material 135 that encapsulates the die 114 (e.g., on and around die 114 and interconnects 150). The overmold material 135 may extend from a top surface of the second substrate 148-2 to a top surface of the die 114. In some embodiments, the overmold material 135 may be a mold material, such as an organic polymer with inorganic silicon oxide or aluminum oxide particles, a resin material, or an epoxy material. In some embodiments (not shown) other components, such as heat sinks may be coupled to microelectronic assembly 100 based on particular needs. In some embodiments, the overmold material 135 is a same material as the insulating material 133. In some embodiments, the overmold material 135 is a different material than the insulating material 133.

The microelectronic assembly 100 of FIG. 1A may also include an underfill material 127. In some embodiments, the underfill material 127 may extend between die 114-1, 114-2 and the second substrate 148-2 around the associated interconnects 150. The underfill material 127 may be an insulating material, such as an appropriate epoxy material. In some embodiments, the underfill material 127 may include a capillary underfill, non-conductive film (NCF), or molded underfill. In some embodiments, the underfill material 127 may include an epoxy flux that assists with soldering die 114-1, 114-2 to the second substrate 148-2 when forming the interconnects 150, and then polymerizes and encapsulates the interconnects 150. The underfill process may include dispensing underfill material in liquid form, allowing the material to flow and fill the interstitial gaps around interconnects 150, and subjecting the assembly to a curing process, such as baking, to solidify the material. In some embodiments, an underfill material 127 may be omitted. Although FIG. 1A shows two separate underfill 127 portions under die 114-1 and die 114-2, the underfill 127 may be a single underfill 127 under die 114-1 and die 114-2. The underfill material 127 may be selected to have a coefficient of thermal expansion (CTE) that may mitigate or minimize the stress between die 114 and the second substrate 148-2 arising from uneven thermal expansion in the microelectronic assembly 100. In some embodiments, the CTE of the underfill material 127 may have a value that is intermediate to the CTE of the second substrate 148-2 (e.g., the CTE of the dielectric material of the substrate 148) and a CTE of the insulating material of die 114.

The microelectronic assembly 100 of FIG. 1 may also include a circuit board 131. In particular, conductive contacts 172 on a bottom surface of the first substrate 148-1 may be electrically coupled to conductive contacts 146 on a top surface of circuit board 131 by interconnects 190. Interconnects 190 disclosed herein may take any suitable form, including solder balls for a ball grid array arrangement, pins in a pin grid array arrangement or lands in a land grid array arrangement, or any of the forms described above with reference to interconnects 150. As shown in FIG. 1A, in some embodiments, a set of interconnects 190 may include solder 136 (e.g., solder bumps or balls that are subject to a thermal reflow to form the interconnects 190). In some embodiments, the interconnects 190 disclosed herein may have a pitch between about 50 microns and 300 microns. In some embodiments, an underfill material 127 may extend between the first substrate 148-1 and the circuit board 131 around the associated interconnects 190. The circuit board 131 may be a motherboard, for example, and may have other components attached to it. The circuit board may include conductive pathways and other conductive contacts for routing power, ground, and signals through the circuit board, as known in the art. In some embodiments, the interconnects 190 may not couple to a circuit board 131, but may instead couple to another IC package, an interposer, or any other suitable component.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

FIG. 2A shows a schematic cross-sectional view of another example microelectronic assembly 100 according to some embodiments of the present disclosure. The configuration of the embodiment shown in the figure is like that of FIG. 1, except for differences as described further. The configuration of microelectronic assembly 100 as described herein except that a core 103 includes a first glass layer 103-1 having TGVs 110-1 on a second glass layer 103-2 having TGVs 110-2, where the first and second glass layers are bonded together by interconnects 106 to form a core 103 and ultra-high aspect ratio TGVs 110. The configuration of microelectronic assembly 100 further includes dies 114-1, 114-2 electrically coupled to a top surface of substrate 148-2 by interconnects 106, for example, hybrid bonds.

FIG. 2B shows a schematic cross-sectional view of another example microelectronic assembly 100 according to some embodiments of the present disclosure. The configuration of the embodiment shown in the figure is like that of FIG. 1, except for differences as described further. The configuration of microelectronic assembly 100 as described herein except that a core 103 includes a first glass layer 103-1 having TGVs 110-1, a second glass layer 103-2, on the first glass layer 103-1, having TGVs 110-2, and a third glass layer 103-3, on the second glass layer 103-2, having TGVs 110-3 bonded together by interconnects 106 to form a core 103 and ultra-high aspect ratio TGVs 110.

FIG. 2B shows a schematic cross-sectional view of another example microelectronic assembly 100 according to some embodiments of the present disclosure. The configuration of the embodiment shown in the figure is like that of FIG. 1, except for differences as described further. The configuration of microelectronic assembly 100 as described herein except that a core 103 includes a first glass layer 103-1 having TGVs 110-1, a second glass layer 103-2, on the first glass layer 103-1, having TGVs 110-2, and a third glass layer 103-3, on the second glass layer 103-2, having TGVs 110-3 bonded together by interconnects 106 to form a core 103 and ultra-high aspect ratio TGVs 110.

FIG. 2C shows a schematic cross-sectional view of another example microelectronic assembly 100 according to some embodiments of the present disclosure. The configuration of the embodiment shown in the figure is like that of FIG. 1, except for differences as described further. The configuration of microelectronic assembly 100 as described herein except that a core 103 includes a five glass layers 103-1, 103-2, 103-3, 103-4, 103-5, having respective TGVs 110-1, 110-2, 110-3, 110-4, 110-5, where the five glass layers 103-1, 103-2, 103-3, 103-4, 103-5 are stacked with respective TGVs 110-1, 110-2, 110-3, 110-4, 110-5 vertically aligned and bonded together by interconnects 106 to form a core 103 and ultra-high aspect ratio TGVs 110.

Although FIGS. 1 and 2 show a particular number and arrangement of components (e.g., glass cores 103, TGVs 110, substrates 148, and die 114), a microelectronic assembly 100 may have any suitable number and arrangement of components, including two glass layers 103-1, 103-2 bonded together or three or more glass layers 103-1, 103-2, 103-3 bonded together. In some embodiments, a microelectronic assembly 100 may have six, seven, or more than seven glass layers bonded together.

FIG. 3A is a schematic cross-sectional view of a magnified portion of an example microelectronic assembly according to some embodiments of the present disclosure. The configuration of the embodiment shown in the figure is like that of FIG. 1A, except for differences described further. The configuration is a magnified portion of a microelectronic assembly 100 including a core 103 and an insulating material 133. The core 103 includes three glass layers 103-1, 103-2, 103-3 having respective TGVs 110-1, 110-2, 110-3 that are bonded together to form the core 103 and TGVs 110 having a thickness of 191. The individual TGVs 110-1, 110-2, 110-3 are vertically misaligned (e.g., include an offset 195, 197). In particular, second TGVs 110-2 are misaligned from first TGVs 110-1 by a first offset 195 and third TGVs 110-3 are misaligned from first TGVs 110-1 by a second offset 197. The first offset 195 and the second offset 197 may be between 1 micron and 50% of a diameter 193 of a TGV 110. For example, as described above with reference to FIG. 1, a diameter 193 of a TGV 110 may be between 5 microns and 100 microns, such that, for a TGV 110 having a diameter 193 equal to 5 microns, an offset 195, 197 may be between 1 micron and 2.5 microns, and, for a TGV 110 having a diameter equal to 100 microns, an offset 195, 197 may be between 1 micron and 50 microns. In some embodiments, the first offset 195 is a same dimension as the second offset 197. In some embodiments, the first offset 195 has a different dimension than the second offset 197. Although FIG. 3A shows each of the first TGVs 110-1 having a same offset 195, 197 as each of the second TGVs 110-2 and the third TGVs 110-3, respectively, the offset 195, 197 may vary for each individual second TGV 110-2 and each individual third TGV 110-3. In some embodiments, one or more of the first TGVs 110-1 may not be vertically misaligned with one or more of the second TGVs 110-2 and/or the third TGVs 110-3, respectively (e.g., may not have an offset 195, 197). The configuration of the figure further shows the individual TGVs 110-1, 110-2, 110-3 having an hourglass shape (e.g., a narrower diameter 193-1 towards a middle of the TGV 110 and a larger diameter 193-2 towards a surface of the individual glass layers 103-1, 103-2, 103-3).

FIG. 3B is a schematic cross-sectional view of a magnified portion of an example microelectronic assembly according to some embodiments of the present disclosure. The configuration of the embodiment shown in the figure is like that of FIG. 1A, except for differences described further. The configuration is a magnified portion of a microelectronic assembly 100 including a core 103, an interface material 105, and an insulating material 133. The core 103 includes three glass layers 103-1, 103-2, 103-3 having respective TGVs 110-1, 110-2, 110-3 that are bonded together by an interface material 105 between the glass layers 103-1, 103-2, 103-3 to form the core 103 and TGVs 110. The interface material 105 may include any suitable material including an inorganic dielectric, such as silicon oxide, or an organic dielectric, such as a polyimide. The interface material 105 may function as a buffer layer between the glass layers 103-1, 103-2, 103-3 or may function as a bonding layer (e.g., as part of the interconnects 106 forming oxide-oxide bond). In some embodiments, a thickness (e.g., z-height) of the interface material 105 is between 0.1 micron and 50 microns.

FIG. 3C is a schematic cross-sectional view of a magnified portion of an example microelectronic assembly according to some embodiments of the present disclosure. The configuration of the embodiment shown in the figure is like that of FIG. 1A, except for differences described further. The configuration is a magnified portion of a microelectronic assembly 100 including a core 103, an interface material 107, a liner material 109, and an insulating material 133. The core 103 includes three glass layers 103-1, 103-2, 103-3 having respective TGVs 110-1, 110-2, 110-3, an interface material 107 between the glass layers 103-1, 103-2, 103-3, and a liner material 109 between the TGVs 110-1, 110-2, 110-3 and the respective glass layer 103-1, 103-2, 103-3. The interface material 105 may include any suitable material including inorganic dielectric or an organic dielectric, such as a polyimide. The interface material 105 may function as a buffer layer between the glass layers 103-1, 103-2, 103-3 or may function as a bonding layer (e.g., as part of the interconnects 106 forming oxide-oxide bonds). A liner material 109 may include any suitable material for lining a via opening in the respective glass layers 103-1, 103-2, 103-3, including a liquid dielectric (e.g., a liquid organic dielectric including inorganic fillers), parylene, or an organic dielectric, such as a polyimide. The liner material 109 may function to reduce cracks, fractures, or breaks in the glass layers 103-1, 103-2, 103-3 due to stress during formation of the TGVs 110-1, 110-2, 110-3 and/or during manufacturing of the microelectronic assembly 100. In some embodiments, an interface material 107 is a same material as a liner material 109. In some embodiments, a thickness (e.g., y-dimension/length or x-dimension/width) of the liner material 109 is between 0.1 micron and 10 microns.

FIG. 4A is a schematic cross-sectional view of another example microelectronic assembly 100 according to some embodiments of the present disclosure. The configuration of the embodiment shown in the figure is like that of FIG. 1, except for differences as described further. The configuration of microelectronic assembly 100 as described herein further includes a bridge die 202. A bridge die 202 may be at least partially within a dielectric material of the second substrate 148-2 (e.g., at least partially nested in a cavity). The bridge die 202 may be electrically coupled to dies 114 (e.g., die 114-1 and die 114-2) by interconnects 150. In particular, conductive contacts 122 on the bottom surface of dies 114 may be electrically and mechanically coupled to the conductive contacts 124 on the top surface of the bridge die 202 by interconnects 150. A bridge die 202 may comprise appropriate circuitry on/in a semiconductor substrate to connect at silicon-interconnect speeds with a small footprint. In some embodiments, bridge die 202 may comprise active components, such as transistors and diodes in addition to bridge circuitry including metallization traces, vias and passive components for enabling electrical coupling between two ICs; in other embodiments, bridge die 202 may include bridge circuitry including metallization traces, vias and passive components for enabling electrical coupling between die 114-1 and die 114-2, and may not include active components.

FIG. 4B is a schematic cross-sectional view of another example microelectronic assembly 100 according to some embodiments of the present disclosure. The configuration of the embodiment shown in the figure is like that of FIG. 4A, except for differences as described further. The configuration of microelectronic assembly 100 as described herein does not include an insulating material 133 (e.g., around the core 103, as shown in FIG. 4A) and further includes a double-sided bridge die 202. A bridge die 202 may be at least partially within a dielectric material of the second substrate 148-2 (e.g., at least partially nested in a cavity). The bridge die 202 may be electrically coupled to dies 114 (e.g., die 114-1 and die 114-2) by interconnects 150 and to conductive pathways 196 in the second substrate 148-2 by interconnects 120. In particular, conductive contacts 122 on a bottom surface of the bridge die 202 may be electrically coupled to a conductive pathway 196 (e.g., a conductive trace in a metal layer) of the second substrate 148-2. In some embodiments, bridge die 202 may include through substrate vias (TSVs) (not shown).

FIG. 4C is a schematic cross-sectional view of another example microelectronic assembly 100 according to some embodiments of the present disclosure. The configuration of the embodiment shown in the figure is like that of FIG. 1B, except for differences as described further. The configuration of microelectronic assembly 100 as described herein includes the first, second, and third glass layers 103-1, 103-2, 103-3 stacked with the first, second, and third TGVs 110-1, 110-2, 110-3 aligned vertically and electrically coupled by interconnects 152 to form the core 103 and TGVs 110. In particular, conductive contacts on a bottom surface of the first glass layer 103-1 may be electrically coupled to conductive contacts on a top surface of the second glass layer 103-2 by interconnects 190, and conductive contacts on a top surface of the first glass layer 103-1 may be electrically coupled to conductive contacts on a bottom surface of the third glass layer 103-3 by interconnects 152. Interconnects 152 disclosed herein may take any suitable form, including any of the forms described above with reference to interconnects 150. As shown in FIG. 4C, in some embodiments, a set of interconnects 152 may include solder (e.g., solder bumps or balls that are subject to a thermal reflow to form the interconnects 152).

Any suitable techniques may be used to manufacture the microelectronic assemblies 100 disclosed herein. For example, FIGS. 5A-5G are side, cross-sectional views of various stages in an example process for manufacturing the microelectronic assembly 100 of FIG. 1, in accordance with various embodiments. Although the operations discussed below with reference to FIGS. 5A-5G (and others of the accompanying drawings representing manufacturing processes) are illustrated in a particular order, these operations may be performed in any suitable order. Further, additional operations which are not illustrated may also be performed without departing from the scope of the present disclosure. Also, various ones of the operations discussed herein with respect to FIGS. 5A-5G may be modified in accordance with the present disclosure to fabricate others of microelectronic assembly 100 disclosed herein.

FIG. 5A illustrates an assembly including a first glass layer 103-1 having a first surface 570-1 and a second surface 570-2. The first glass layer 103-1 has first TGVs 110-1. The first TGVs 110-1 may include any suitable conductive material, for example, copper. The first glass layer 103-1 may have any suitable dimensions, for example, the first glass layer 103-1 may include a full panel glass core having a surface area of approximately 500 millimeters by 500 millimeters (e.g., xy-dimension), or may include a quarter panel glass core having a surface area of approximately 250 millimeters by 250 millimeters. The assembly of FIG. 5A may be manufactured by forming vias openings in the first glass layer 103-1, and plating copper in the via openings to form TGVs 110-1. The via openings may be formed using any suitable process, including lithography, laser assisted wet etch, laser drilling (e.g., laser ablation using excimer laser), or plasma etching. The via openings may have any suitable shape. For example, the via openings may have substantially vertical sidewalls to form rectangular-shaped vias, may have angled sidewalls to form conical-shaped vias, or may have double angled sidewalls to form hourglass-shaped vias. The shape of the via openings may depend on the process used to form the via openings (e.g., a lithographic process for rectangular-shaped vias and a laser drilling process for conical-shaped vias).

FIG. 5B illustrates an assembly subsequent to aligning and bonding second glass layers 103-2 having second TGVs 110-2 to a bottom surface 570-1 of the first glass layer 103-1 having first TGVs 110-1 by interconnects 106, and subsequent to aligning and bonding third glass layers 103-3 having second TGVs 110-3 to a top surface 570-2 of the first glass layer 103-1 having first TGVs 110-1 by interconnects 106. The second and third glass layers 103-2, 103-3 may have any suitable dimensions, for example, the second and third glass layers 103-2, 103-3 may have a surface area (e.g., xy-dimension) between 20 millimeters by 20 millimeters and 250 millimeters by 250 millimeters. In some embodiments, a surface area of the second and third glass layers 103-2, 103-3 is between 20 millimeters by 20 millimeters and 50 millimeters by 50 millimeters (e.g., between 400 square millimeters and 2,500 square millimeters). The assembly of FIG. 5B may be subjected to appropriate bonding processing to form interconnects 106. For example, the bonding process may include applying a suitable pressure and heating to a suitable temperature (e.g., to moderately high temperatures, e.g., between about 50 and 300 degrees Celsius) for a duration of time. Additional glass layers may be added to the assembly of FIG. 5B (e.g., fourth and fifth glass layers 103-4, 103-5, as shown in FIG. 2C, may be aligned and bonded to the respective second and third glass layers 103-2, 103-3 by interconnects 106). In some embodiments, first and second surfaces 570-1, 570-2 of the first glass layer 103-1 and/or respective surfaces 170-1, 170-2 of the second and third glass layers 103-2, 103-3 may be planarized prior to bonding together. The respective surfaces 570-1, 570-2, 170-1, 170-2 may be planarized using any suitable technique, including etching (e.g., selective wet metal etching and selective glass etching, such as a wet etch using sodium hydroxide or hydrofluoric acid), or grinding (e.g., chemical mechanical polishing (CMP)).

FIG. 5C illustrates an assembly subsequent to depositing an insulating material 133 on the top and bottom surfaces of the assembly of FIG. 5B (e.g., surfaces 570-1, 570-2, 170-1, 170-2 and on and around second and third glass layers 103-2, 103-3). The insulating material 133 may be formed using any suitable technique, including lamination. FIG. 5C further illustrates a core 103 and TGVs 110 formed subsequent to bonding the individual glass layers 103-1, 103-2, 103-3 and individual TGVs 110-1, 110-2, 110-3 by interconnects 106.

FIG. 5D illustrates an assembly subsequent to removing the insulating material 133 from a top surface 170-2 and a bottom surface 170-2 of the core. The insulating material 133 may be removed and, optionally, planarized, using any suitable technique, including grinding (e.g., CMP).

FIG. 5E illustrates an assembly subsequent to forming substrates 148-1, 148-2 on respective surfaces 170-1, 170-2 of the core 103, attaching dies 114-1, 114-2 to a top surface of the second substrate 148-2 by forming interconnects 150, depositing an underfill material 127, depositing an overmold material 135 on and around the dies 114-1, 114-2, and performing surface finishing operations, such as depositing solder resist (not shown) and solder 136 at a bottom surface of the first substrate 148-1. The assembly of FIG. 5E may be manufactured using conventional package substrate manufacturing techniques. The dielectric of the substrate 148 may be deposited using any suitable technique, including lamination, and may be removed using any suitable technique, such as laser patterning or lithography, to form a cavity for placing a bridge die 202 (not shown) therein. The conductive pathways 196 may be any suitable conductive material, such as copper, silver, nickel, gold, aluminum, or other metals or alloys, and may be deposited using any suitable process, including lithography, electrolytic plating, or electroless plating.

FIG. 5F illustrates microelectronic assemblies 100 subsequent to singulation. The microelectronic assemblies 100 may be formed by sawing through the assembly of FIG. 5E to form individual microelectronic assemblies 100 having a core 103 with TGVs 110 and an insulating material 133.

FIG. 5G illustrates microelectronic assemblies 100 subsequent to singulation. The microelectronic assemblies 100 may be formed by sawing through the assembly of FIG. 5E to form individual microelectronic assemblies 100 having a core 103 with TGVs 110 and not having an insulating material 133 (e.g., the insulating material 133 was removed during the singulation process).

The assemblies of FIGS. 5F and 5G may themselves be microelectronic assemblies 100, as shown. Further manufacturing operations may be performed on the microelectronic assemblies 100 of FIGS. 5F and 5G to form other microelectronic assemblies 100; for example, attaching a circuit board 131 to a bottom surface of the microelectronic assemblies 100 of FIGS. 5F and 5G by forming interconnects 190, similar to FIG. 1.

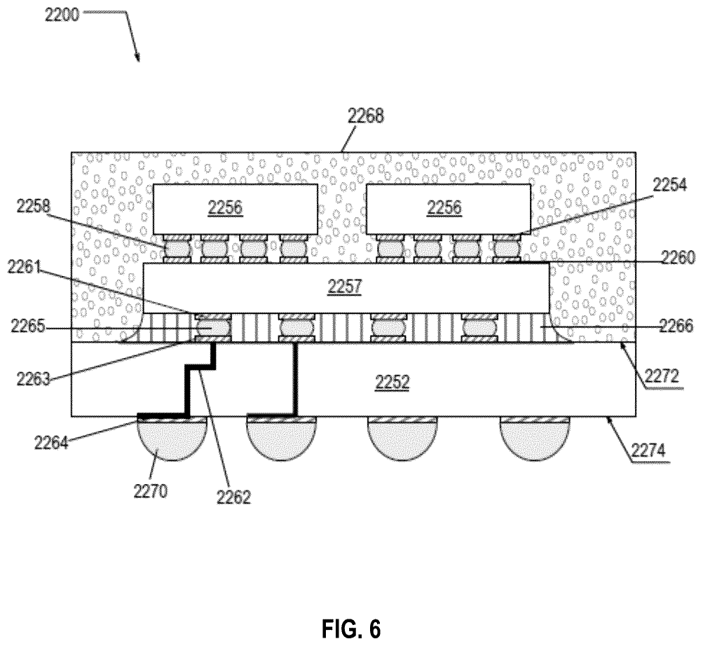

The packages disclosed herein, e.g., any of the microelectronic assemblies 100, or any further embodiments described herein, may be included in any suitable electronic component. FIGS. 6-8 illustrate various examples of packages, assemblies, and devices that may be used with or include any of the IC packages as disclosed herein.

FIG. 6 is a side, cross-sectional view of an example IC package 2200 that may include microelectronic assemblies in accordance with any of the embodiments disclosed herein. In some embodiments, the IC package 2200 may be a system-in-package (SiP).

As shown in FIG. 6, package support 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures including lines and/or vias, e.g., as discussed above with reference to FIG. 1.

Package support 2252 may include conductive contacts 2263 that are coupled to conductive pathway 2262 through package support 2252, allowing circuitry within dies 2256 and/or interposer 2257 to electrically couple to various ones of conductive contacts 2264 (or to other devices included in package support 2252, not shown).

IC package 2200 may include interposer 2257 coupled to package support 2252 via conductive contacts 2261 of interposer 2257, first level interconnects (FLI) 2265, and conductive contacts 2263 of package support 2252. FLI 2265 illustrated in FIG. 6 are solder bumps, but any suitable FLI 2265 may be used, such as solder bumps, solder posts, or bond wires.

IC package 2200 may include one or more dies 2256 coupled to interposer 2257 via conductive contacts 2254 of dies 2256, FLI 2258, and conductive contacts 2260 of interposer 2257. In various embodiments, interposer 2257 may include core 103 including glass as described herein. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). FLI 2258 illustrated in FIG. 6 are solder bumps, but any suitable FLI 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

In some embodiments, underfill material 2266 may be disposed between package support 2252 and interposer 2257 around FLI 2265, and mold 2268 may be disposed around dies 2256 and interposer 2257 and in contact with package support 2252. In some embodiments, underfill material 2266 may be the same as mold 2268. Example materials that may be used for underfill material 2266 and mold 2268 are epoxies as suitable. Second level interconnects (SLI) 2270 may be coupled to conductive contacts 2264. SLI 2270 illustrated in FIG. 6 are solder balls (e.g., for a ball grid array (BGA) arrangement), but any suitable SLI 2270 may be used (e.g., pins in a pin grid array arrangement or lands in a land grid array arrangement). SLI 2270 may be used to couple IC package 2200 to another component, such as a circuit board (e.g., a motherboard), an interposer, or another IC package, as known in the art and as discussed below with reference to FIG. 8.

In embodiments in which IC package 2200 includes multiple dies 2256, IC package 2200 may be referred to as a multichip package (MCP). Dies 2256 may include circuitry to perform any desired functionality. For example, besides one or more of dies 2256 including components of dies 114 as described herein, one or more of dies 2256 may be logic dies (e.g., silicon-based dies), one or more of dies 2256 may be memory dies (e.g., high-bandwidth memory), etc. In some embodiments, at least some of dies 2256 may not include components of dies 114 as described herein.

Although IC package 2200 illustrated in FIG. 6 is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package support 2252, or on either face of interposer 2257. More generally, IC package 2200 may include any other active or passive components known in the art.

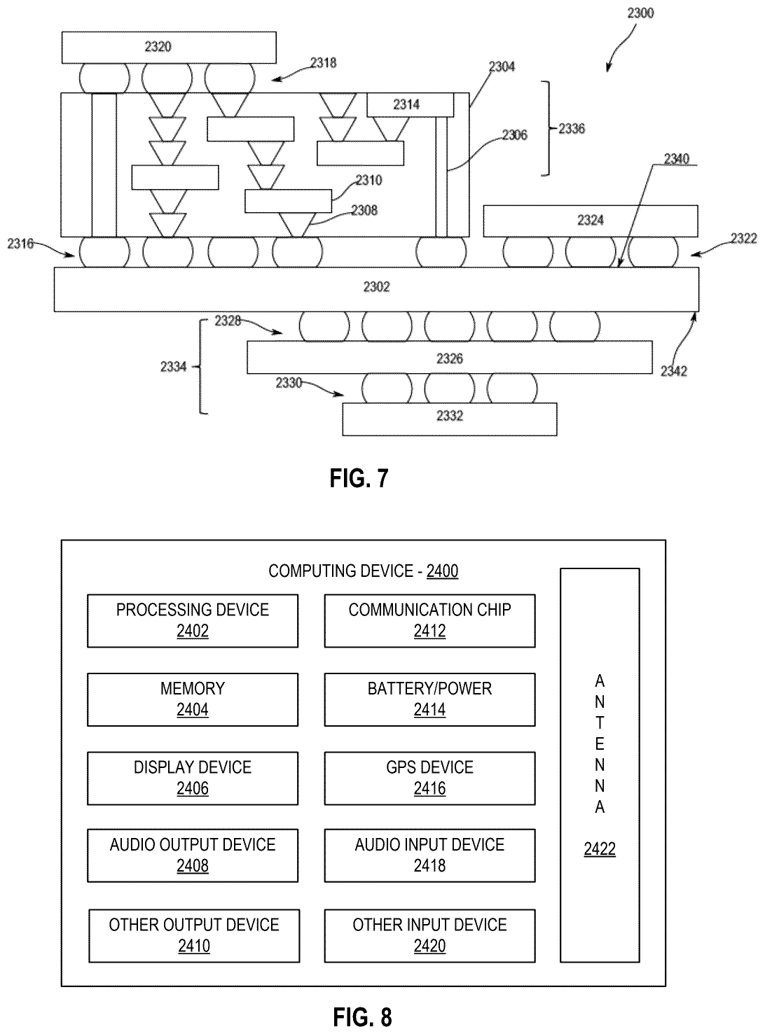

FIG. 7 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 6.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package support.

FIG. 7 illustrates that, in some embodiments, IC device assembly 2300 may include a package-on-interposer structure 2336 coupled to first face 2340 of circuit board 2302 by coupling components 2316. Although not shown so as not to clutter the drawing, package-on-interposer structure 2336 may include a core 103, such as glass layer, in some embodiments. In other embodiments, package-on-interposer structure 2336 may not include a core. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. In some embodiments, IC package 2320 may include microelectronic assembly 100, and other components as described herein, which are not shown so as not to clutter the drawing. Coupling components 2318 may take any suitable form depending on desired functionalities, such as the forms discussed above with reference to coupling components 2316. In some embodiments, IC package 2320 may be or include IC package 2200, e.g., as described above with reference to FIG. 6.

Although a single IC package 2320 is shown in FIG. 7, multiple IC packages may be coupled to interposer 2304; indeed, additional interposers may be coupled to interposer 2304. Interposer 2304 may provide an intervening package support used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in FIG. 7, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group Ill-V and group IV materials. Interposer 2304 may include metal interconnects 2308 and vias 2310, including TSVs 2306. Interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

FIG. 8 is a block diagram of an example computing device 2400 that may include one or more components having one or more IC packages in accordance with any of the embodiments disclosed herein. For example, any suitable ones of the components of computing device 2400 may include microelectronic assembly 100 including glass in accordance with any of the embodiments disclosed herein. In another example, any one or more of the components of computing device 2400 may include any embodiments of IC package 2200 (e.g., as shown in FIG. 6). In yet another example, any one or more of the components of computing device 2400 may include an IC device assembly 2300 (e.g., as shown in FIG. 7).

A number of components are illustrated in FIG. 8 as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SOC die.

Additionally, in various embodiments, computing device 2400 may not include one or more of the components illustrated in FIG. 8, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more digital signal processors (DSPs), ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-MRAM).

In some embodiments, computing device 2400 may include a communication chip 2412 (e.g., one or more communication chips; note that the terms “chip,” “die,” and “IC die” are used interchangeably herein). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives of it, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

The following paragraphs provide various examples of the embodiments disclosed herein.

Example 1 is a microelectronic assembly, including a first glass layer including a first conductive through-glass via (TGV); and a second glass layer including a second conductive TGV, wherein the second glass layer is on and bonded to the first glass layer, the second conductive TGV is electrically coupled to the first conductive TGV, and the first conductive TGV and the second conductive TGV have an aspect ratio between 20:1 and 50:1.

Example 2 may include the subject matter of Example 1, and may further specify that a thickness of the first conductive TGV is between 50 microns and 1 millimeter.

Example 3 may include the subject matter of Example 1 or 2, and may further specify that a thickness of the second conductive TGV is between 50 microns and 1 millimeter.

Example 4 may include the subject matter of any of Examples 1-3, and may further specify that a diameter of the first conductive TGV is between 5 microns and 100 microns.

Example 5 may include the subject matter of any of Examples 1-4, and may further specify that a diameter of the second conductive TGV is between 5 microns and 100 microns.

Example 6 may include the subject matter of any of Examples 1-5, and may further specify that an overall thickness of the first conductive TGV electrically coupled to the second conductive TGV is between 100 microns and 2 millimeters.

Example 7 may include the subject matter of any of Examples 1-6, and may further specify that the first conductive TGV is vertically misaligned from the second conductive TGV.

Example 8 may include the subject matter of any of Examples 1-7, and may further include a material between the first glass layer and the second glass layer, wherein the material includes an organic dielectric or an inorganic dielectric.

Example 9 may include the subject matter of any of Examples 1-8, and may further include a liner material between the first conductive TGV and the first glass layer, wherein the liner material includes a liquid organic dielectric, polyimide, or parylene.

Example 10 may include the subject matter of any of Examples 1-9, and may further include a third glass layer including a third conductive TGV, wherein the third glass layer is on the second glass layer and physically bonded to the second glass layer, the third conductive TGV is electrically coupled to the second conductive TGV, and the first conductive TGV, the second conductive TGV, and the third conductive TGV have an aspect ratio between 30:1 and 50:1.

Example 11 is a microelectronic assembly, including a first glass layer including a first conductive through-glass via (TGV); and a second glass layer including a second conductive TGV, wherein the second glass layer is on and bonded to the first glass layer, the second conductive TGV is electrically coupled to the first conductive TGV, and the first conductive TGV is vertically misaligned from the second conductive TGV.

Example 12 may include the subject matter of Example 11, and may further specify that the first conductive TGV and the second conductive TGV have an aspect ratio between 20:1 and 50:1.

Example 13 may include the subject matter of Example 11 or 12, and may further specify that the first conductive TGV has a first thickness between 50 microns and 1 millimeter, and the second conductive TGV has a second thickness between 50 microns and 1 millimeter.

Example 14 may include the subject matter of any of Examples 11-13, and may further specify that the first conductive TGV has a first diameter between 5 microns and 100 microns, and the second conductive TGV has a second diameter between 5 microns and 100 microns.

Example 15 may include the subject matter of any of Examples 11-14, and may further include a material between the first glass layer and the second glass layer, wherein the material includes an organic dielectric or an inorganic dielectric.

Example 16 is a microelectronic assembly, including a plurality of stacked glass layers, each glass layer of the plurality of stacked glass layers including a conductive through-glass via (TGV) having a thickness between 50 microns and 1 millimeter and a diameter between 20 microns and 100 microns, wherein adjacent glass layers in the plurality of stacked glass layers are bonded together and adjacent conductive TGVs in the plurality of stacked glass layers are electrically coupled and have an aspect ratio between 20:1 and 50:1; a first dielectric material at a bottom surface of the plurality of stacked glass layers, the first dielectric material including a first conductive pathway, the first conductive pathway electrically coupled to the conductive TGV at the bottom surface of the plurality of stacked glass layers; and a second dielectric material at a top surface of the plurality of stacked glass layers, the second dielectric material including a second conductive pathway, the second conductive pathway electrically coupled to the conductive TGV at the top surface of the plurality of stacked glass layers.

Example 17 may include the subject matter of Example 16, the plurality of stacked glass layers includes between 2 and 5 glass layers.

Example 18 may include the subject matter of Example 16 or 17, and may further include a material between each glass layer of the plurality of stacked glass layers, wherein the material includes an organic dielectric or an inorganic dielectric.

Example 19 may include the subject matter of any of Examples 16-18, and may further include a die on the second dielectric material and electrically coupled to the second conductive pathway in the second dielectric material.

Example 20 may include the subject matter of any of Examples 16-19, and may further include a circuit board at a bottom of the first dielectric material and electrically coupled to the first conductive pathway.

1. A microelectronic assembly, comprising:
a first glass layer including a first conductive through-glass via (TGV); and
a second glass layer including a second conductive TGV, wherein the second glass layer is on and bonded to the first glass layer, the second conductive TGV is electrically coupled to the first conductive TGV, and the first conductive TGV and the second conductive TGV have an aspect ratio between 20:1 and 50:1.

2. The microelectronic assembly of claim 1, wherein a thickness of the first conductive TGV is between 50 microns and 1 millimeter.

3. The microelectronic assembly of claim 1, wherein a thickness of the second conductive TGV is between 50 microns and 1 millimeter.

4. The microelectronic assembly of claim 1, wherein a diameter of the first conductive TGV is between 5 microns and 100 microns.

5. The microelectronic assembly of claim 1, wherein a diameter of the second conductive TGV is between 5 microns and 100 microns.

6. The microelectronic assembly of claim 1, wherein an overall thickness of the first conductive TGV electrically coupled to the second conductive TGV is between 100 microns and 2 millimeters.

7. The microelectronic assembly of claim 1, wherein the first conductive TGV is vertically misaligned from the second conductive TGV.

8. The microelectronic assembly of claim 1, further comprising:
a material between the first glass layer and the second glass layer, wherein the material includes an organic dielectric or an inorganic dielectric.

9. The microelectronic assembly of claim 1, further comprising:
a liner material between the first conductive TGV and the first glass layer, wherein the liner material includes a liquid organic dielectric, polyimide, or parylene.

10. The microelectronic assembly of claim 1, further comprising:
a third glass layer including a third conductive TGV, wherein the third glass layer is on the second glass layer and physically bonded to the second glass layer, the third conductive TGV is electrically coupled to the second conductive TGV, and the first conductive TGV, the second conductive TGV, and the third conductive TGV have an aspect ratio between 30:1 and 50:1.

11. A microelectronic assembly, comprising:
a first glass layer including a first conductive through-glass via (TGV); and
a second glass layer including a second conductive TGV, wherein the second glass layer is on and bonded to the first glass layer, the second conductive TGV is electrically coupled to the first conductive TGV, and the first conductive TGV is vertically misaligned from the second conductive TGV.

12. The microelectronic assembly of claim 11, wherein the first conductive TGV and the second conductive TGV have an aspect ratio between 20:1 and 50:1.

13. The microelectronic assembly of claim 11, wherein the first conductive TGV has a first thickness between 50 microns and 1 millimeter, and the second conductive TGV has a second thickness between 50 microns and 1 millimeter.

14. The microelectronic assembly of claim 11, wherein the first conductive TGV has a first diameter between 5 microns and 100 microns, and the second conductive TGV has a second diameter between 5 microns and 100 microns.

15. The microelectronic assembly of claim 11, further comprising:
a material between the first glass layer and the second glass layer, wherein the material includes an organic dielectric or an inorganic dielectric.

16. A microelectronic assembly, comprising:
a plurality of stacked glass layers, each glass layer of the plurality of stacked glass layers including a conductive through-glass via (TGV) having a thickness between 50 microns and 1 millimeter and a diameter between 20 microns and 100 microns, wherein adjacent glass layers in the plurality of stacked glass layers are bonded together and adjacent conductive TGVs in the plurality of stacked glass layers are electrically coupled and have an aspect ratio between 20:1 and 50:1;
a first dielectric material at a bottom surface of the plurality of stacked glass layers, the first dielectric material including a first conductive pathway, the first conductive pathway electrically coupled to the conductive TGV at the bottom surface of the plurality of stacked glass layers; and
a second dielectric material at a top surface of the plurality of stacked glass layers, the second dielectric material including a second conductive pathway, the second conductive pathway electrically coupled to the conductive TGV at the top surface of the plurality of stacked glass layers.

17. The microelectronic assembly of claim 16, the plurality of stacked glass layers includes between 2 and 5 glass layers.

18. The microelectronic assembly of claim 16, further comprising:
a material between each glass layer of the plurality of stacked glass layers, wherein the material includes an organic dielectric or an inorganic dielectric.

19. The microelectronic assembly of claim 16, further comprising:
a die on the second dielectric material and electrically coupled to the second conductive pathway in the second dielectric material.

20. The microelectronic assembly of claim 16, further comprising:
a circuit board at a bottom of the first dielectric material and electrically coupled to the first conductive pathway.
